(19) United States
(12) Patent Application Publication
(10) Pub. No.: US 2025/0266237 A1
(43) Pub. Date: Aug. 21, 2025

(54) REFLECTANCE CONFOCAL SCANNING ELECTRON MICROSCOPE AND OPERATING METHOD THEREOF

(71) Applicant: Samsung Electronics Co., Ltd., Suwon-si (KR)

(72) Inventors: CHANGHYEONG YOON, Suwon-si (KR); TAEJOONG KIM, Suwon-si (KR); INHO SHIN, Suwon-si (KR); KIHUN KANG, Suwon-si (KR); JIYONG SHIN, Suwon-si (KR); TAEYONG JO, Suwon-si (KR); HYUKJOON CHO, Suwon-si (KR)

(21) Appl. No.: 18/825,349

(22) Filed: Sep. 5, 2024

(30) Foreign Application Priority Data
Feb. 20, 2024 (KR) 10-2024-0024013

(51) Int. Cl. H01J 37/29; H01J 37/10

(52) U.S. Cl. CPC H01J 37/292; H01J 37/10; H01J 2237/0451; H01J 2237/0492

(57) ABSTRACT

A reflectance confocal scanning electron microscope according to of the present inventive concept may include, a first column device configured to allow an electron beam to be incident on a sample, and a second column device configured to de-scan the electron beam after it is reflected from the sample to confocally detect electrons emitted from the sample.

### CROSS-REFERENCE TO RELATED APPLICATION(S)

This application claims benefit of priority to Korean Patent Application No. 10-2024-0024013 filed on Feb. 20, 2024 in the Korean Intellectual Property Office, the disclosure of which is incorporated herein by reference in its entirety.

### BACKGROUND OF THE INVENTION

The present inventive concept relates to a reflectance confocal scanning electron microscope and a method of operating the same.

Generally, an SEM (Scanning Electron Microscope) is a scientific instrument used to observe the surface structure of small objects at high resolution. The SEM employs electrons to probe the surface of a sample and converts that information into images. It scans the sample with an electron beam and generates images. This electron beam possesses concentrated high energy and interacts with the sample surface to acquire various information. The SEM scans the electron beam onto the sample surface to generate electron signals on the surface. In doing so, it measures the interaction between electrons and the sample to obtain various information such as surface structure, composition, defects, and crystal structure of the sample.

### SUMMARY OF THE INVENTION

An aspect of the present inventive concept is to provide a novel reflectance confocal scanning electron microscope and a method of operating the same.

An aspect of the present inventive concept is to provide a reflectance confocal scanning electron microscope for measuring and inspecting high-resolution semiconductor structures and a method of operating the same.

According to an aspect of the present inventive concept, a reflectance confocal scanning electron microscope includes: a first column device configured to allow an electron beam to be incident on a sample; and a second column device configured to de-scan the electron beam after it is reflected from the sample to confocally detect electrons emitted from the sample.

According to an aspect of the present inventive concept, a reflectance confocal scanning electron microscope includes: an objective lens configured to focus electrons scattered from a sample; and a spatial filter configured to confocally filter an electron beam focused through the objective lens

According to an aspect of the present inventive concept, a reflectance confocal scanning electron microscope includes: a first column device configured to apply an electron beam to a sample; and a second column device including a detector that is configured to detect the electron beam. The electron beam may scan the sample as it is incident on the sample. The electron beam may pass through a pinhole toward the detector as a de-scanned electron beam.

According to an aspect of the present inventive concept, a method of operating a reflectance confocal scanning electron microscope includes: acquiring a three-dimensional volume matrix using confocal filtering and de-scanning through the reflectance confocal scanning electron microscope; and measuring a three-dimensional structure using the three-dimensional volume matrix.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a conceptual diagram of a general scanning electron microscope;

FIG. 2 is a diagram illustrating a reflectance confocal scanning electron microscope according to an embodiment of the present inventive concept;

FIG. 3 is a diagram illustrating a plan view of a reflectance confocal scanning electron microscope according to an embodiment of the present inventive concept;

FIG. 4 is a diagram conceptually illustrating confocal filtering of a reflectance confocal scanning electron microscope according to an embodiment of the present inventive concept;

FIG. 5 is a diagram conceptually illustrating de-scanning of a reflectance confocal scanning electron microscope according to an embodiment of the present inventive concept;

FIG. 6 is a diagram illustrating sample scanning with a reflectance confocal scanning electron microscope according to an embodiment of the present inventive concept;

FIGS. 7A, 7B, and 7C are diagrams illustrating example enhancements in horizontal resolution and contrast of a reflectance confocal scanning electron microscope according to an embodiment of the present inventive concept;

FIGS. 8A, 8B, and 8C are diagrams illustrating example enhancements in vertical resolution of a reflectance confocal scanning electron microscope according to an embodiment of the present inventive concept;

FIGS. 9A and 9B are diagrams illustrating example non-destructive 3D structure measurement of a reflectance confocal scanning electron microscope according to an embodiment of the present inventive concept;

FIG. 10 is a diagram illustrating measurement flexibility of a reflectance confocal scanning electron microscope according to an embodiment of the present inventive concept;

FIG. 11 is a flowchart illustrating a semiconductor measurement system having a reflectance confocal scanning electron microscope according to an embodiment of the present inventive concept;

FIG. 12 is a flowchart illustrating an example operation of measuring a 3D structure of a reflectance confocal scanning electron microscope according to an embodiment of the present inventive concept; and

FIG. 13 is a diagram illustrating a computing device processing measurement signals of a reflectance confocal scanning electron microscope according to an embodiment of the present inventive concept.

### DETAILED DESCRIPTION

Hereinafter, example embodiments of the present inventive concept will be described with reference to the accompanying drawings.

As semiconductor device structures become more miniaturized and complex, there is an increasing demand for inspection capabilities regarding defects or margin-related issues. This demand cannot be met solely by surface information anymore. Conventional methods for inspecting such defects involve grinding, stress-testing, CMP (Chemical Mechanical Polishing) processes, etc., to reach the respective layers for measurement. However, these methods fail to meet the high throughput (TPT; Throughput) and inspection coverage required in high-volume manufacturing processes. Such defects or issues significantly impact yield and reliability. Therefore, non-destructive 3D structural measurement technology is required.

Typically, an SEM (Scanning Electron Microscope) provides nanometer-level resolution and is a direct imaging inspection/measurement tool. The SEM collects electrons emitted from the interaction volume of electrons incident on the sample at the detector and constructs the sample's image using intensity information from the focal point of the beam. Secondary electrons generally provide surface profile information, while backscattered electrons offer property information in contrast format. Thus, the SEM can measure defects or critical dimensions (CD; Critical Dimension) on the sample surface.

Embodiments of the invention disclose a reflectance confocal scanning electron microscope and an operating method for high-resolution semiconductor structure measurement and inspection. According to embodiments of the invention, the reflectance confocal scanning electron microscope may perform high-contrast SEM imaging, depth sectioning, and 3D structural measurement. The reflectance confocal scanning electron microscope according to embodiments of the invention may include an electron source, a condenser lens, an aperture, a scanning deflector, a first objective lens (illumination), a second objective lens (detection), a de-scanning deflector, a spatial filter (or pinhole), and a detector.

According to embodiments of the invention, the reflectance confocal scanning electron microscope and the operating method may obtain high-contrast images and improve resolution by removing noise with a spatial filter. Depth sectioning for 3D structural measurement with high axial resolution can also be achieved. Various scan modes can be implemented, and compared to a conventional SEM, the reflectance confocal scanning electron microscope according to embodiments of the invention offers improved contrast and resolution effects and enables 3D structural measurement.

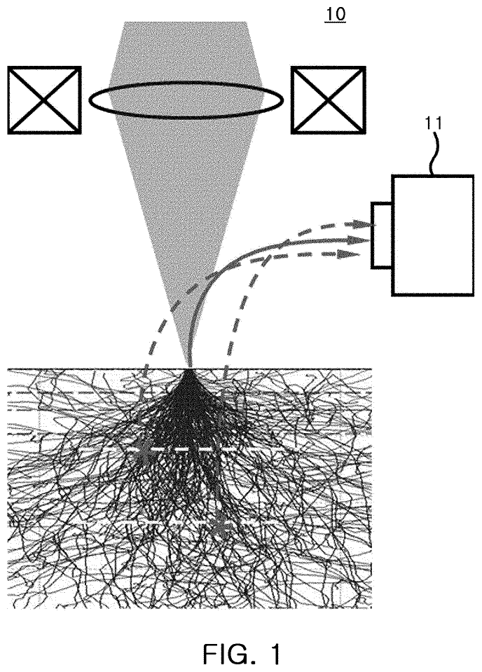

FIG. 1 is a conceptual diagram of a general scanning electron microscope (SEM) 10. Referring to FIG. 1, the SEM 10 detects electron beams scattered from a sample using a detector 11. As shown in FIG. 1, a basic principle of the SEM 10 is to focus accelerated electrons onto a surface of the sample and measure the electrons emitted from the sample by the detector 11 to acquire information regarding the surface of the sample. When an electron beam is focused on the sample, an interaction volume is formed according to acceleration conditions. Electrons scattered at different depths are randomly spread around a landing spot and emitted externally, thereby being collected in the detector 11. The SEM 10 forms a two-dimensional image by scanning a spot.

However, in the case of such non-imaging detection, not only a focused point but also electrons spreading and rising from points below are detected, leading to the deterioration of the final image resolution compared to the spot size. This inevitably results in a loss of resolution. Additionally, distinguishing or filtering electrons emitted at different depths is challenging, causing surface signals to mix with underlying signals and making it difficult to implement depth sectioning. Consequently, acquiring accurate information regarding a three-dimensional structure may be challenging.

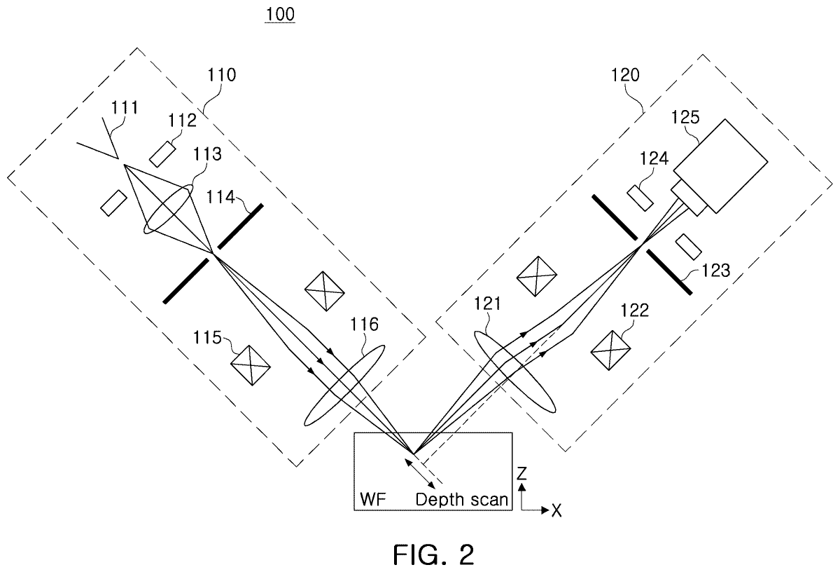

FIG. 2 is a diagram illustrating a reflectance confocal scanning electron microscope (RCSEM) 100 according to an embodiment of the present inventive concept. Referring to FIG. 2, the reflectance confocal scanning electron microscope 100 may include a first column device 110 and a second column device 120.

The first column device 110 may be implemented to emit an electron beam, control a probe size of the emitted electron beam, and irradiate the controlled electron beam onto a sample WF. The first column device 110 may thus allow (e.g., direct/control) the electron beam to be incident on the sample WF. The first column device 110 may include an electron source 111, an anode 112, a condensing lens 113, an aperture 114, a scanning coil 115 and an objective lens 116.

The electron source 111 may be implemented to emit an electron beam. The electron source 111 may be implemented as an electron gun. In general, an electron gun may be implemented in a thermal emission form, that is, in a manner that generates heat and emits electrons. The electron gun may mainly use a thermionic emitter to emit electrons. The thermionic emitter may operate at high temperatures to generate electrons. Typically, a specific metal or alloy may be used as a catalyst. Such a metal may emit electrons when heated at high temperature. The electron gun may generate electrons and then accelerate the electrons to form an electron beam. This acceleration may allow the electrons to have higher energy when they impact the sample, which is useful when observing a detailed structure of the sample. Additionally, the electron gun may include various elements for controlling the electron beam. For example, the electron gun may have a beam modulation function to adjust an amplitude or direction of the electron beam. Meanwhile, in addition to the thermionic electron type, the electron beam may be emitted in a Schottky method or a cold field emission method.

The anode 112 may be implemented to accelerate the electron beam after it is generated by the electron source 111. The anode 112 may provide voltage to accelerate the electrons. The anode 112 may be made of a metal with positive charges. Such a metal may be used to rapidly attract and accelerate the electrons. An increase in voltage due to the anode 112 may allow the electron beam to impact an object with higher energy.

The condensing lens 113 may be implemented to primarily condense the accelerated electron beam (i.e., the electron beam after it is accelerated by the anode 112). The condensing lens 113 may uniformly project the electron beam onto the surface of the sample WF by adjusting the size/direction of the electron beam.

The aperture 114 may be implemented to pass the focused electron beam (i.e., the electron beam after it is focused/condensed by the condensing lens 113) corresponding to the probe size. In an embodiment, a size of a probe (i.e., a “probe size”) on the surface of the sample WF may be determined depending on (e.g., may be controlled by, and thus based on) a size of the aperture 114 and a magnification of the RCSEM 100.

The scanning coil 115 may be implemented to change a direction of flow of the electron beam passing through (e.g., after it passes through) the aperture 114 using a magnetic field. The scanning coil 115 may be referred to as a deflector. Typically, a deflector may change a flow direction of an electron beam by changing Lorentz force generated on electrons using a magnetic field. The scanning coil 115 may control the flow of the electron beam to scan the surface of the sample.

The objective lens 116 may be implemented to focus the electron beam on the sample surface. In an embodiment, the objective lens 116 may further include a stigmator and an aberration corrector to correct distortion of a shape of the probe spot (e.g., a “probe spot shape,” which may be a shape of the electron beam on the surface of the sample WF). The stigmator may correct the electron beam so that it is accurately focused on the surface of the sample, and may improve image resolution by correcting a stigma effect occurring in an electro-optical system. This may minimize image distortion and increase accuracy by controlling irregular conditions in a path of the electron beam. The stigmator may mainly improve contrast of images and correct irregular shapes to create clearer images. The aberration corrector may improve resolution of images by correcting optical anomalies in a lens or lens system. The aberration corrector may minimize image distortion by correcting various optical abnormalities (e.g., distortion, diffused light, focusing, etc.) that may occur in the lens or lens system. Such a correction may optimize an optical performance of the lens system, thereby increasing image sharpness and resolution. The use of an aberration corrector may acquire accurate images by correcting an angle of incidence of the electron beam and the configuration of the optical system.

The second column device 120 may be implemented to detect (e.g., de-scan) the electron beam after it is reflected from the sample WF. The second column device 120 may include a second objective lens 121, a de-scanning coil 122, a spatial filter 123, an energy filter 124 and a detector 125.

The second objective lens 121 may be implemented to focus the electron beam reflected from the sample WF. The second objective lens 121 may collect scattered electrons emitted from the sample WF (e.g., emitted in response to scanning the sample WF with an electron beam). For example, after collecting the scattered electrons, the second objective lens 121 may focus the scattered electrons as an electron beam. By implementing one-to-one imaging detection by introducing an objective lens in signal detection, electrons only with an emission angle matching a light reception angle of the objective lens may be selectively transferred to the detector 125. As a result, it may be expected to have a primary noise attenuation effect. In some embodiments, a focal length of the second objective lens 121 may be adjustable. Additionally, resolution may be improved by using the objective lens. The general formula for resolution is as follows:

$$Δ xy = \frac{1.22 λ}{{NA}_{illum} + {NA}_{collec}} \qquad [ Equation 1 ]$$

$$Δ z = \frac{λ}{{( \frac{{NA}_{illum} + {NA}_{collec}}{2} )}^{2}}$$

A final resolution may be inversely proportional to a sum of illumination NA (NAᵢₗₗᵤₘ) and light reception NA (NA_{collec}). Accordingly, imaging resolution may be increased by increasing the acquisition objective lens NA.

The de-scanning coil 122 may perform de-scanning to focus the electrons emitted from the sample WF on the spatial filter 123. As the electrons emitted from the sample WF pass through the objective lens 121, the direction of the electron beam may change. The de-scanning may be performed because the electrons emitted from the sample WF must pass through the spatial filter 123 positioned in a confocal plane. The de-scanning coil 122 may de-scan an electron beam after it is focused through the objective lens 121 and before it passes through the spatial filter 123 (e.g., a pinhole). The de-scanning coil 122 may be referred to as de-scanning deflector. Components to pass through the spatial filter 123 may be determined according to a beam control of the de-scanning deflector. For this reason, a point to be detected in the sample WF may be defined.

The RCSEM 100 of the present inventive concept may use a focus control function of the detection objective lens and a scan function of the de-scanning deflector without a separate stage movement or focused point scanning, whereby information within the electronic interaction volume of the sample WF may be imaged in a variety of scanning modes.

The spatial filter 123 may be referred to as a pinhole configured to confocally filter the electron beam after it is focused through/by the objective lens 121. The focused point/electron beam de-scanned by the de-scanning coil 122 may pass through the pinhole. At this time, components occurring outside a point to be measured may be blurred or blocked on the pinhole, and electrons only occurring at the target position/depth may be received. This may improve contrast and resolution of a final image. In an embodiment, a resolution, a signal to noise ratio (SNR), etc. may be adjusted depending on (e.g., may be controlled by, and thus based on) a selection of a size of the pinhole. Optimization may be necessary depending on measurement conditions and samples.

The energy filter 124 may be implemented to accelerate the electrons passing (e.g., an electron beam after it passes) through the pinhole. The electrons passing through the pinhole may pass through an appropriate energy filter or acceleration filter and be incident on the detector 125. The detector 125 may thus detect an electron beam after it passes through the pinhole. The energy filter 124 may perform various methods/operations used to adjust an energy of an electron beam. For example, the energy filter 124 may control the energy of the electrons by adjusting a voltage. The energy filter 124 may adjust the voltage when passing the electron beam therethrough, allowing electrons only in a specific energy range to pass through. Additionally, the energy filter 124 may be used to analyze energy distribution of the electrons. Through this, information regarding specific characteristics or structure of the sample may be acquired. For example, the energy distribution of the electrons may be affected by specific atoms or bonding states in the sample. By measuring and analyzing this energy distribution using the energy filter 124, information regarding the chemical or structural properties of the sample may be acquired.

The detector 125 may be implemented to receive the electron beam passing through the energy filter 124 and convert the electron beam into a corresponding electrical signal. A final 2D (two-dimensional) image may be acquired by a focused point and a scan of the detector scanning. The second column device 120 may acquire the 2D image of the sample WF through confocal detection of electrons emitted from the sample WF. The detector 125 may detect and measure signals generated after the electron beam interacts with the sample WF. The detector 125 may generate images related to the sample WF or analyze the characteristics of the sample, by collecting/processing the result of interaction with the electron beam.

In an embodiment, the detector 125 may include a backscattered electron detector, a secondary electron detector, an X-ray spectrometer, a backscattered electron imaging detector and the like. The backscatter detector may detect reflected electrons when an electron beam collides with a sample. These electrons may provide information related to the sample's density or an atomic number, thereby being mainly used to observe a structure and a composition of the sample. The secondary scattering detector may detect secondary scattered electrons generated when the electron beam interacts with a surface of the sample. Since these electrons are related to surface properties of the sample, they may be used in surface morphography and defect detection. The X-ray spectrometer may detect X-rays produced when an electron beam interacts with the sample. These X-rays may be used to analyze a chemical composition of the sample. The backscatter imaging detector may produce images based on an energy or intensity of backscattered electrons. Through this, information regarding the density or composition of the sample may be acquired.

The detector 125 may be used to generate a scanning electron microscope image or analyze the characteristics of the sample by detecting and analyzing the result of the electron beam interacting with the sample. This may allow the scanning electron microscope to measure internal and surface structures of the sample and various materials.

The reflectance confocal scanning electron microscope 100 according to an embodiment of the present inventive concept may acquire high-resolution images compared to conventional/general electron microscopes, improve SNR and increase image contrast, measure 3D structures by performing depth sectioning, support various scanning modes, restore 3D structures through modeling/learning and improve patterning inspection by applying multi-beam technology.

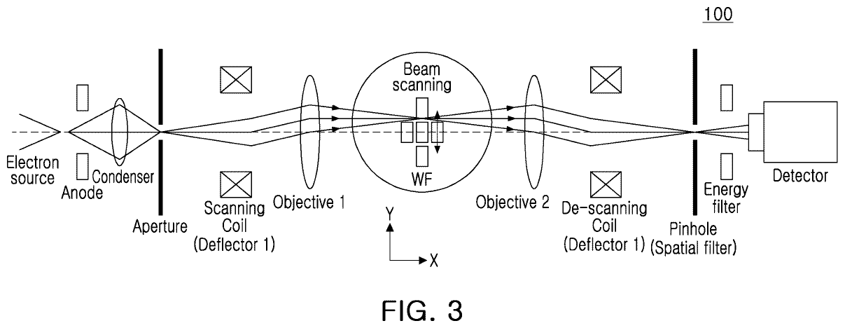

FIG. 3 is a diagram illustrating a plan view of a reflectance confocal scanning electron microscope according to an embodiment of the present inventive concept. Referring to FIG. 3, the reflectance confocal electron microscope may include an electron source, an anode, a condenser, an aperture, a scanning coil (a first deflector), a first objective lens, a second objective lens, a de-scanning coil (a second deflector), a pinhole (a spatial filter), an energy filter and a detector.

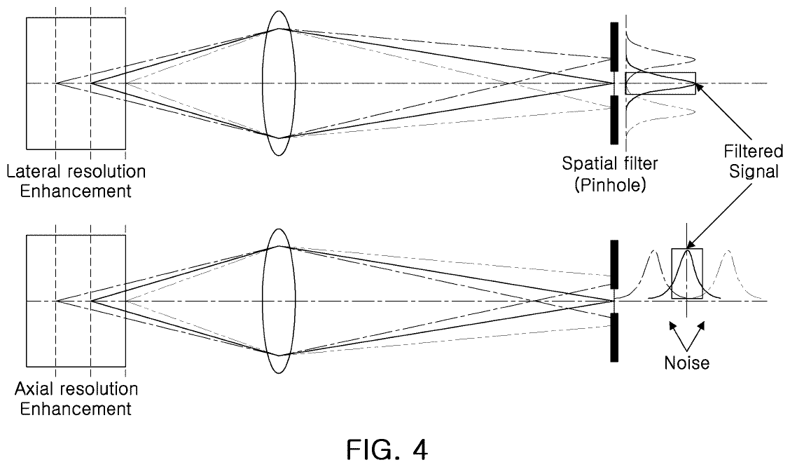

FIG. 4 is a diagram conceptually illustrating confocal filtering of a reflectance confocal scanning electron microscope according to an embodiment of the present inventive concept. As shown in FIG. 4, a spatial filter (or a pinhole) may be positioned at a position in conjugation with a focal plane. Beams coming from positions other than a focus may be blocked by the spatial filter, thereby improving XY resolution. On the other hand, signals emitted from depths different from the focal plane may spread in the spatial filter plane, so an SNR of the signals for a target depth may increase, and depth resolution and contrast may be improved. Components other than those from the focal plane may act as noise and degrade resolution and SNR. The pinhole may be in a position conjugated to (e.g., intersecting/combined with) the focal plane, and may have a diameter corresponding to a transfer function (PSF) of the optical system, allowing only focused signals to pass through. Typically, resolution may be enhanced by more than 40% in axial/lateral directions.

The reflectance confocal scanning electron microscope 100 according to an embodiment of the present inventive concept may improve resolution and image contrast by introducing the above-described confocal microscopy technology into an SEM. The principle of confocal microscopy may improve an SNR by spatially filtering signals only generated at the focused point, and depth resolution may be enhanced by blocking components occurring at depths other than the focal plane. In an embodiment, compared to a conventional SEM, the RCSEM of the present inventive concept may have an effect of enhancing resolution by at least 1.4 times. Further improvements may be possible depending on the power of a lens used, aberration control and filtering conditions. The reflectance confocal scanning electron microscope of the present inventive concept may not only significantly improve the resolution of existing SEMs, but also acquire depth-specific high-resolution images under high acceleration conditions, whereby it may be used for a 3D structure measurement and a defect inspection.

The reflectance confocal scanning electron microscope 100 according to an embodiment of the present inventive concept may improve contrast and spatial resolution of SEM images through confocal imaging technology, and may measure a 3D structure that could not be measured with a conventional SEM.

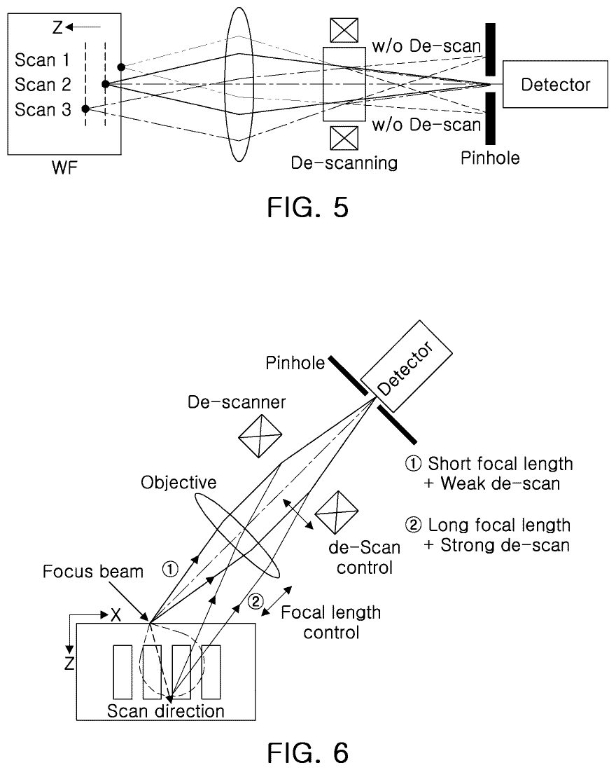

FIG. 5 is a diagram conceptually illustrating de-scanning of a reflectance confocal scanning electron microscope 100 according to an embodiment of the present inventive concept. Referring to FIG. 5, an electron beam may be delivered to a center of a pinhole through a de-scanning control (e.g., a de-scanning control operation performed by the de-scanning coil 122 of FIG. 2) according to a scanning point for each location. Signals coming from various locations on a sample may be delivered to different locations after passing through an objective lens. Since all signals in the respective scanning points must undergo confocal filtering, they may be controlled to consistently pass through the center of the pinhole through the de-scanning. Any scanning mode for the sample may be implemented through the objective lens and the de-scanning control.

FIG. 6 is a diagram illustrating sample scanning with a reflectance confocal scanning electron microscope 100 according to an embodiment of the present inventive concept. An electron beam focused on a sample may create an interaction volume inside the sample. By controlling a focal length of an objective lens and a de-scanner, the sample may be precisely scanned (e.g., by an electron beam) without a driving unit for any target volume. In an embodiment, the scanning method may be a combination of a short focal length and a weak de-scan (\textcircled{1}), or a combination of a long focal length and a strong de-scan (\textcircled{2}). Since lateral resolution is generally better than axial resolution, a decrease in resolution in a direction of depth of the sample may be compensated for with a tilted column.

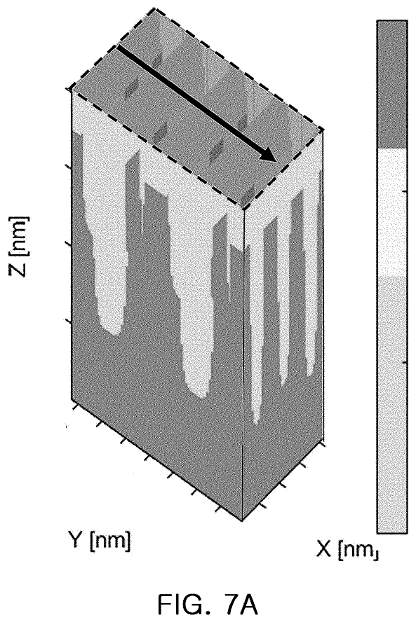

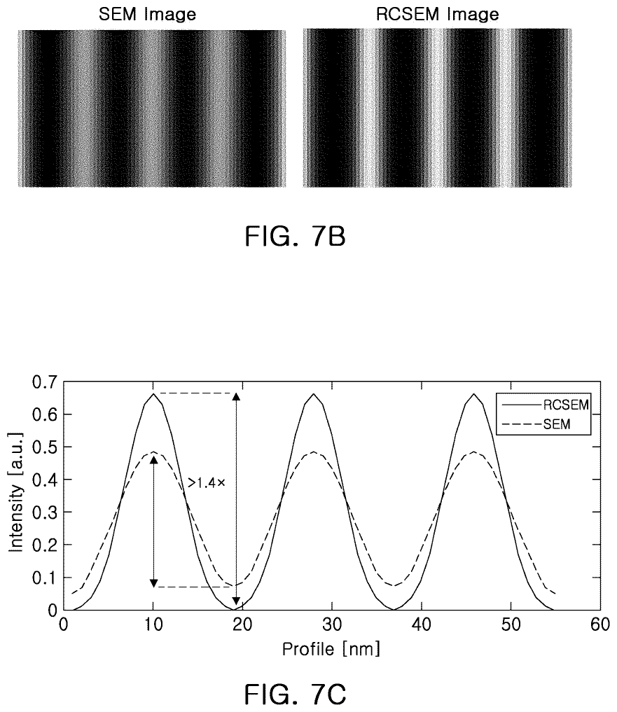

FIGS. 7A, 7B, and 7C are diagrams illustrating example enhancements in horizontal resolution and contrast of a reflectance confocal scanning electron microscope according to an embodiment of the present inventive concept. For the plan view of a three-dimensional sample shown in FIG. 7A, an image of a conventional SEM and an image of the RCSEM of the present inventive concept may be measured as shown in FIG. 7B. At this time, as shown in FIG. 7C, a profile related to intensity may be acquired. Resolution and contrast may be enhanced by approximately 40% through noise suppression. Optimal resolution may be selected according to sample conditions for a pinhole control. Measurement sensitivity and defect detection ability may be enhanced compared to the existing SEM.

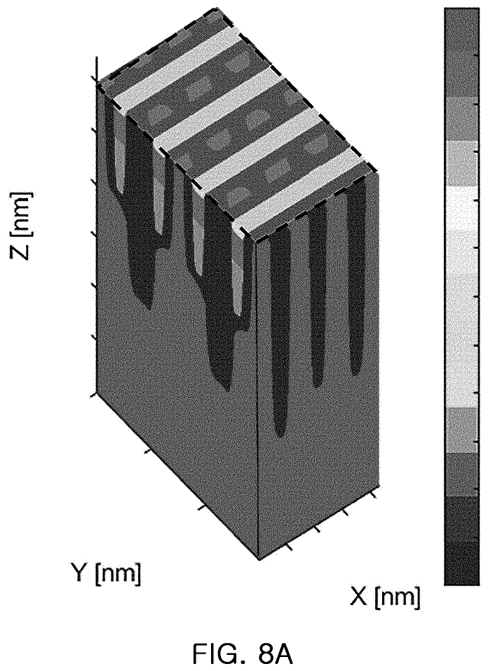

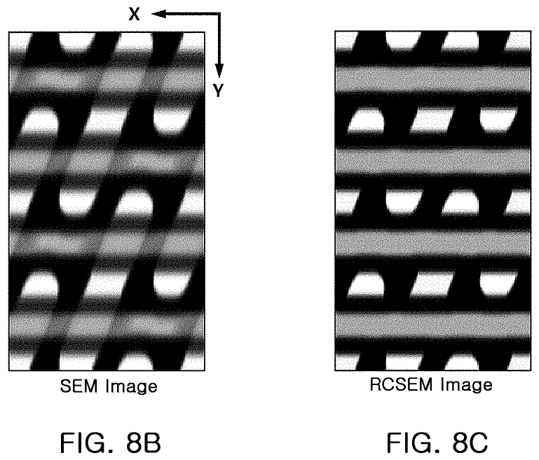

FIGS. 8A, 8B, and 8C are diagrams illustrating example enhancements in vertical resolution of a reflectance confocal scanning electron microscope according to an embodiment of the present inventive concept. For a sample shown in FIG. 8A, FIG. 8B is a plan view image according to a conventional SEM, and FIG. 8C is a confocally filtered image of the plan view image according to the RCSEM of the present inventive concept. As shown in FIG. 8B, the conventional SEM may distinguish signals coming from different depths. On the other hand, as shown in FIG. 8C, the RCSEM of the present inventive concept may improve depth resolution by more than 7 times by applying confocal detection. In addition, the RCSEM of the present inventive concept enables selective depth-specific measurement without a separate driver by adjusting a focal power of an objective lens at a detection stage.

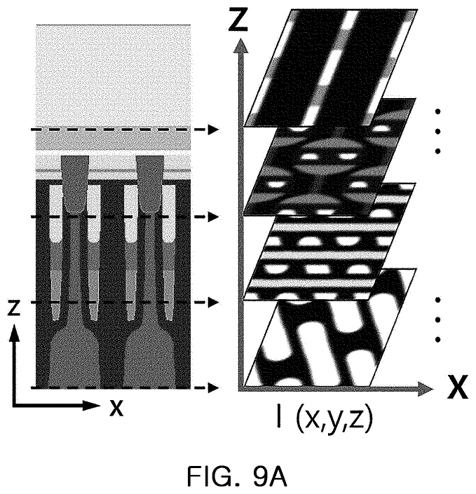

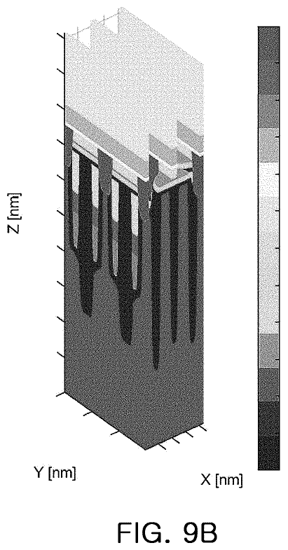

FIGS. 9A and 9B are diagrams illustrating example non-destructive 3D structure measurement of a reflectance confocal scanning electron microscope 100 according to an embodiment of the present inventive concept. As shown in FIG. 9A, the RCSEM of the present inventive concept may acquire depth-specific tomography results. As shown in FIG. 9B, the RCSEM of the present inventive concept may restore a three-dimensional structure by image processing images of the depth-specific tomography results. The RCSEM of the present inventive concept may provide the ability to measure the three-dimensional structure of a wafer sample by processing tomography images using a graphics design system (GDS) and model-based image processing. In addition, the RCSEM of the present inventive concept may non-destructively inspect existing destructive analysis items, such as a lower CD margin, a misalignment (M/A), and a defect (D/F).

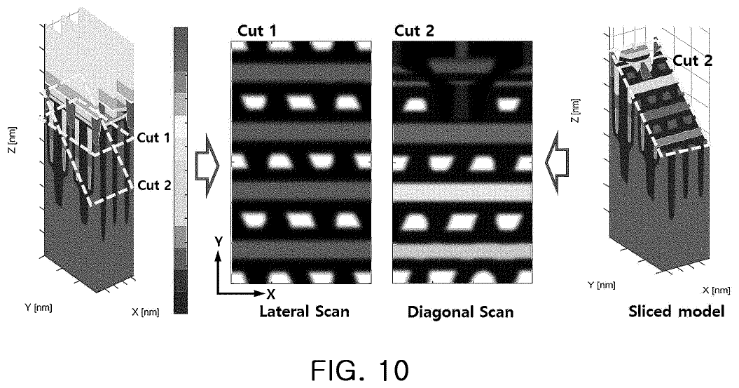

FIG. 10 is a diagram illustrating measurement flexibility of a reflectance confocal scanning electron microscope 100 according to an embodiment of the present inventive concept. As shown in FIG. 10, the RCSEM of the present inventive concept may implement various scanning modes by adjusting a focal length of a lens of a detection stage by position. A conventional SEM can only acquire surface information, so Cut 2 cannot be implemented.

The RCSEM of the present inventive concept may provide slice images in a direction to be measured by using a focal length and a de-scanning control of an objective lens of a detection column. In addition, the RCSEM of the present inventive concept may provide measurement flexibility for each target CD and strengthen a process response by supporting various 2D scanning modes that could not be implemented with a conventional SEM.

The reflectance confocal scanning electron microscope according to an embodiment of the present inventive concept may improve in axial/lateral directions resolution through confocal filtering, enable a 3D structure reconstruction through high-precision depth-sectioning, provide measurement flexibility (scanning mode) by introducing a separate detection column, and provide a non-destructive measurement solution.

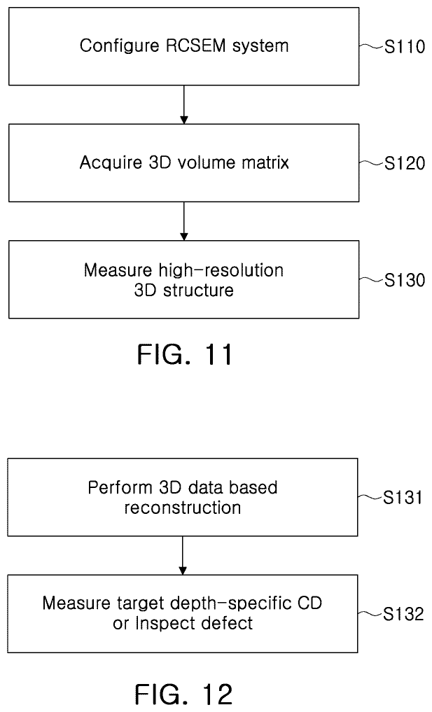

FIG. 11 is a flowchart illustrating a semiconductor measurement system having a reflectance confocal scanning electron microscope according to an embodiment of the present inventive concept. With reference to FIGS. 1 to 11, the semiconductor measurement system may operate as follows. A semiconductor measurement system with a reflectance confocal scanning electron microscope may be configured/constructed (S110). A 3D volume matrix may be acquired through a reflectance confocal scanning electron microscope (S120). A high-resolution 3D structure may be measured using the 3D volume matrix (S130).

In an embodiment, the 3D volume matrix may be acquired by adjusting a focal length or focal refractive power of an objective lens. In an embodiment, a de-scanning coil may be adjusted for de-scanning. In an embodiment, a size of a pinhole may be adjusted for confocal filtering.

FIG. 12 is a flowchart illustrating an example operation of measuring a 3D structure of a reflectance confocal scanning electron microscope according to an embodiment of the present inventive concept. Referring to FIG. 12, a 3D data-based reconstruction may be performed in the reflectance confocal scanning electron microscope according to an embodiment of the present inventive concept (S131). Then, a target depth-specific CD (critical dimension) may be measured or defects may be inspected (S132).

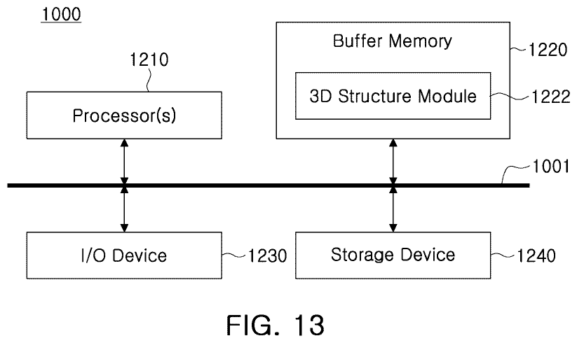

FIG. 13 is a diagram illustrating a computing device 1000 processing measurement signals of a reflectance confocal scanning electron microscope according to an embodiment of the present inventive concept. Referring to FIG. 13, a computing device 1000 may include at least one processor 1210, a memory device 1220 (e.g., a buffer memory), an input/output device 1230 and a storage device 1240, connected to a system bus 1001. Through the system bus 1001, the processor 1210, the memory device 1220, the input/output device 1230 and the storage device 1240 may be electrically connected to each other, and may exchange data with each other. A configuration of the system bus 1001 is not limited to the above description, and may further include mediation means for efficient management.

The at least one processor 1210 may be implemented to control overall operations of the computing device 1000. The processor 1210 may be implemented to execute at least one instruction. For example, the processor 1210 may be implemented to execute software (an application program, an operating system and device drivers) to be executed in the computing device 1000. The processor 1210 may execute an operating system loaded into the memory device 1220. The processor 1210 may execute various application programs to be driven based on the operating system. For example, the processor 1210 may drive a 3D structure measurement tool (e.g., module) 1222 read from the memory device 1220. In an embodiment, the processor 1210 may be a central processing unit (CPU), a microprocessor, an application processor (AP) or any processing unit similar thereto. In an embodiment, the processor 1210 may be implemented to execute the 3D structure measurement tool 1222.

The memory device 1220 may be implemented to store the at least one instruction. For example, the memory device 1220 may be loaded with the operating system or the application programs. When the computing device 1000 boots, an OS image stored in the storage device 1240 may be loaded into the memory device 1220, based on a booting sequence. All input/output operations of the computing device 1000 may be supported by the operating system. Similarly, the application programs selected by a user or for providing basic services may be loaded into the memory device 1220.

The 3D structure measurement module 1220 may be loaded into the memory device 1220 from the storage device 1240. The 3D structure measurement tool 1222 may measure the 3D structure of the sample based on the measurement data of the RCSEM described in FIGS. 1 to 12.

In addition, the memory device 1220 may be a volatile memory such as a dynamic random access memory (DRAM), a static random access memory (SRAM), or the like, or may be a non-volatile memory such as a flash memory, a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), or the like.

The input/output device 1230 may be implemented to control user input and user output from a user interface device. For example, the input/output device 1230 may receive information from a designer using an input means such as a keyboard, a keypad, a mouse, a touch screen, or the like. Using the input/output device 1230, the designer may receive information regarding a semiconductor region or data paths that require adjusted operating characteristics. In addition, the input/output device 1230 may be equipped with an output means such as a printer, display or the like to display a processing process and results of the 3D structure measurement (e.g., rendering) tool 1222.

The storage device 1240 may be provided as a storage medium of the computing device 1000. The storage device 1240 may store application programs, an OS image, and a measurement tool. The storage device 1240 may be provided as a mass storage device such as a memory card (an MMC, an eMMC, an SD, a Micro SD or the like), a hard disk drive (HDD), a solid state drive (SSD), a universal flash storage (UFS), or the like.

The device described above may be implemented with a hardware component, a software component, and/or a combination of the hardware component and the software component. For example, a device and a component, described in an embodiment, may be implemented using at least one general purpose computer or at least one special purpose computer, such as a processor, a controller, an arithmetic logic unit (ALU), a digital signal processor, a microcomputer, a field programmable gate array (FPGA), a programmable logic unit (PLU), a microprocessor, or any other device capable of executing and responding to an instruction. A processing apparatus may run an operating system (OS) and at least one software application running on the operating system. The processing apparatus may also access, store, manipulate, process, and generate data in response to execution of software. For convenience of understanding, there may be cases in which one processing apparatus is used, but those skilled in the art will understand that the processing apparatus includes a plurality of processing elements or a plurality of types of processing elements. For example, the processing apparatus may include a plurality of processors, or a processor and a controller. A different processing configuration is also possible, such as a parallel processor.

The software may include a computer program, a code, an instruction, or a combination of one or more of the foregoing, which may configure a processing apparatus to operate as desired, or may command the processing apparatus independently or collectively. The software and/or data may be embodied in any type of machine, component, physical device, virtual equipment, computer storage medium or device, intended to be interpreted by or to provide the instruction or the data to the processing apparatus. The software may be distributed on a networked computer system, and may be stored or executed in a distributed manner. The software and the data may be stored on at least one computer readable medium.

This invention discloses a next-generation semiconductor-oriented SEM system that can overcome the limitations of existing SEMs and dramatically improve defect inspection capabilities and structural measurement accuracy. The invention applies the trend of Multi-beam technology in e-Beam technology to enhance TPT.

The scanning electron microscopy technology and method utilizing reflective confocal point detection according to embodiments of the present invention can be implemented as modules of all forms performing reflective confocal point detection by applying separate detection objective lenses, De-scanning Deflectors, and Pinholes. In embodiments, measurements can be performed at arbitrary points on the sample by combining detection objective lenses and deflectors. Methods for adjusting the focal length and focal power of the objective lens may be included in embodiments. Methods for scanning the sample by adjusting the De-scanning Deflector may be included in embodiments. The diameter of the Pinhole serving as the confocal point filter may be fixed or variable in embodiments. The Pinhole serving as the confocal point filter may be fixed or variable in the column axis direction in embodiments.

Implementation of high-resolution SEM imaging technology and 3D structural measurement methods according to embodiments of the present invention can involve using two or more Columns, each equipped with imaging-capable Objectives and Deflectors, or systems utilizing De-Scanning deflector modules and pinholes for space gating, or achieving a resolution and contrast improvement of at least 1.4 times compared to the existing one without separate software processing, or performing depth sectioning and 3D structure reconstruction without using separate modeling or learning methods, or enabling 3D structure measurement for a three-dimensional volume through the selection of vertical stacking processes for next-generation devices.

Conventional SEM technology cannot reduce the selection ratio for electrons emitted from different depths and positions, resulting in resolution loss and inability to perform 3D structure reconstruction. However, the confocal point SEM technology proposed in this invention is a next-generation core e-beam technology that not only improves the resolution of existing SEMs but also provides three-dimensional information about the sample.

A reflectance confocal scanning electron microscope and a method of operating the same according to an embodiment of the present inventive concept may acquire high-contrast images and improve resolution by removing noise with a spatial filter.

A reflectance confocal scanning electron microscope and a method of operating the same according to an embodiment of the present inventive concept may measure a three-dimensional structure by performing depth sectioning with high axial resolution.

A reflectance confocal scanning electron microscope and a method of operating the same according to embodiments of the present inventive concept may be implemented in various scanning modes.

While example embodiments have been shown and described above, it will be apparent to those skilled in the art that modifications and variations could be made without departing from the scope of the present inventive concept as defined by the appended claims.

What is claimed is:

1. A reflectance confocal scanning electron microscope comprising:
a first column device configured to allow an electron beam to be incident on a sample; and
a second column device configured to de-scan the electron beam after it is reflected from the sample to confocally detect electrons emitted from the sample.

2. The reflectance confocal scanning electron microscope of claim 1, wherein the first column device comprises:
an electron source configured to generate the electron beam; and
an objective lens configured to focus the electron beam on the sample.

3. The reflectance confocal scanning electron microscope of claim 2, wherein the first column device further comprises:
an anode configured to accelerate the electron beam after it is generated by the electron source;
a condensing lens configured to condense the electron beam after it is accelerated through the anode; and
an aperture configured to pass the electron beam after it is condensed through the condensing lens,
wherein a probe size for the sample is based on a size of the aperture and a magnification of the reflectance confocal scanning electron microscope.

4. The reflectance confocal scanning electron microscope of claim 3, wherein the first column device further comprises a scanning coil configured to change a direction of the electron beam after it passes through the aperture.

5. The reflectance confocal scanning electron microscope of claim 2, wherein the objective lens further comprises a stigmator or an aberration corrector configured to correct distortion of a probe spot shape.

6. The reflectance confocal scanning electron microscope of claim 1, wherein the second column device comprises:
an objective lens configured to focus the electron beam after it is reflected from the sample;
a pinhole configured to confocally filter the electron beam after it is focused through the objective lens; and
a detector configured to detect the electron beam after it passes through the pinhole.

7. The reflectance confocal scanning electron microscope of claim 6, wherein the second column device further comprises a de-scanning coil configured to de-scan the electron beam after it is focused through the objective lens and before it passes through the pinhole.

8. The reflectance confocal scanning electron microscope of claim 6, wherein the second column device further comprises an energy filter configured to accelerate the electron beam after it passes through the pinhole.

9. The reflectance confocal scanning electron microscope of claim 6, wherein a resolution or a signal-to-noise ratio (SNR) is based on a size of the pinhole.

10. The reflectance confocal scanning electron microscope of claim 1, wherein the second column device is configured to acquire a two-dimensional image of the sample through the confocal detection of the electrons emitted from the sample.

11. A reflectance confocal scanning electron microscope comprising:
an objective lens configured to focus electrons scattered from a sample; and
a spatial filter configured to confocally filter an electron beam focused through the objective lens.

12. The reflectance confocal scanning electron microscope of claim 11, wherein the electrons scatter from the sample in response to scanning the sample.

13. The reflectance confocal scanning electron microscope of claim 12, wherein the electron beam comprises the electrons, the reflectance confocal scanning electron microscope further comprising:
a de-scanning coil configured to de-scan the electron beam that is focused through the objective lens; and
a detector configured to detect the electron beam after it passes through the spatial filter.

14. The reflectance confocal scanning electron microscope of claim 13, wherein the de-scanning coil is configured to perform a de-scanning control operation changing a flow direction of the electron beam.

15. The reflectance confocal scanning electron microscope of claim 11, wherein a focal length of the objective lens is adjustable.

16. A reflectance confocal scanning electron microscope comprising:
a first column device configured to allow an electron beam to be incident on a sample; and
a second column device comprising a detector that is configured to detect the electron beam after it is reflected from the sample,
wherein the electron beam scans the sample as it is incident on the sample, and
wherein the electron beam passes through a pinhole toward the detector as a de-scanned electron beam.

17. The reflectance confocal scanning electron microscope of claim 16, wherein the first column device comprises:
a scanning coil configured to scan the electron beam onto the sample; and
a first objective lens configured to focus the electron beam onto the sample after a direction of the electron beam has been changed by the scanning coil.

18. The reflectance confocal scanning electron microscope of claim 17, wherein the second column device comprises:
a second objective lens configured to focus the electron beam after it is reflected from the sample; and
a de-scanning coil configured to de-scan the electron beam after it passes through the second objective lens.

19. The reflectance confocal scanning electron microscope of claim 16, wherein the second column device is configured to perform confocal filtering through a focal length control adjusting a focal length of an objective lens and a de-scanning control changing a flow direction of the electron beam.

20. The reflectance confocal scanning electron microscope of claim 19, wherein the second column device further comprises an energy filter configured to energy-filter the electron beam after it passes through the pinhole.
